(19) United States
(12) Patent Application Publication
(10) Pub. No.: US 2020/0270392 A1
(43) Pub. Date: Aug. 27, 2020

(54) COMPOSITE FOR FILM FORMATION AND FILM FORMING METHOD

(71) Applicant: TOKYO ELECTRON LIMITED, Tokyo (JP)

(72) Inventor: Tatsuya YAMAGUCHI, Nirasaki City (JP)

(21) Appl. No.: 16/799,106

(22) Filed: Feb. 24, 2020

(30) Foreign Application Priority Data
Feb. 25, 2019 (JP) 2019-031916

(51) Int. Cl. C08G 18/75; C08G 18/38; C09D 175/02; B05D 3/06; B05D 1/00; B05D 7/24

(52) U.S. Cl. CPC C08G 18/755; C08G 18/3819; C09D 175/02; H01L 21/76808; B05D 1/60; B05D 7/24; B05D 3/067

(57) ABSTRACT

There is provided a composite for film formation, including: a first component and a second component that are polymerized with each other to produce a urea compound, wherein at least one of the first component and the second component is a monofunctional compound.

### CROSS-REFERENCE TO RELATED APPLICATION

This application is based upon and claims the benefit of priority from Japanese Patent Application No. 2019-031916, filed on Feb. 25, 2019, the entire contents of which are incorporated herein by reference.

### TECHNICAL FIELD

Various aspects and embodiments of the present disclosure relate to a composite for film formation and a film forming method.

### BACKGROUND

In a process for manufacturing a semiconductor device, a film forming process is performed by supplying a processing gas to a substrate, such as a semiconductor wafer (hereinafter, referred to as a “wafer”). Patent Document 1 discloses a film forming method of forming a film by irradiating an ultraviolet ray to a polyurea film obtained by causing two kinds of monomers to undergo a vapor deposition polymerization on a front surface of a wafer.

### PRIOR ART DOCUMENT

### Patent Documents

Patent Document 1: Japanese Laid-Open Patent Publication No. H07-209864

### SUMMARY

According to an embodiment of the present disclosure, there is provided a composite for film formation, comprising: a first component and a second component that are polymerized with each other to produce a urea compound, wherein at least one of the first component and the second component is a monofunctional compound.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a view illustrating an example of a film forming apparatus according to an embodiment of the present disclosure.

FIG. 2A is a diagram illustrating a polymerization reaction in which a urea film is formed.

FIG. 2B is a diagram illustrating a polymerization reaction in which a urea film is formed.

FIG. 2C is a diagram illustrating a polymerization reaction in which a urea film is formed.

FIG. 3A is a graph illustrating the solubility of a composite for film formation in an embodiment of the present disclosure.

FIG. 3B is a graph illustrating the solubility of the composite for film formation according to the embodiment of the present disclosure, as a comparative example.

FIG. 4A is a cross-sectional view illustrating an example of a workpiece before etching.

FIG. 4B is a cross-sectional view illustrating an example of the workpiece after etching.

FIG. 4C is a cross-sectional view illustrating an example of the workpiece after a resist layer is removed.

FIG. 4D is a cross-sectional view illustrating an example of the workpiece after an anti-reflection film is removed.

FIG. 4E is a cross-sectional view illustrating an example of the workpiece after a urea film is laminated.

FIG. 4F is a cross-sectional view illustrating an example of the workpiece after a cross-linking reaction.

FIG. 4G is a cross-sectional view illustrating an example of the workpiece after the urea film is removed.

FIG. 4H is a cross-sectional view illustrating an example of the workpiece after a cross-linking film is removed.

FIG. 5 is a flowchart illustrating an example of a film forming method according to an embodiment of the present disclosure.

### DETAILED DESCRIPTION

Hereinafter, embodiments of a composite for film formation and a film forming method according to the present disclosure will be described in detail with reference to the accompanying drawings. Further, the technology of the present disclosure is not limited to embodiments to be described below. In addition, it should be noted that the drawings are schematic, and the relationships between dimensions of respective elements, the ratios of the respective elements, and the like may differ from reality. Also, there may be a case where the relationship of dimensions and the ratios differ from each other between the drawings.

There is a composite for film formation by which a polymer film is produced on a front surface of a target substrate by a vapor deposition polymerization of two kinds of raw material monomers. In this type of polymer film, it is difficult to make a molecular weight of a polymer that forms the polymer film uniform.

Because of this, a variation in chemical properties, such as solubility or melting point, occurs in the polymer film depending on a degree of polymerization. For example, in a case where a portion of the polymer film is removed with solvent, if a variation in solubility occurs, it becomes difficult to remove only the portion of the polymer film. This makes it difficult to form a film.

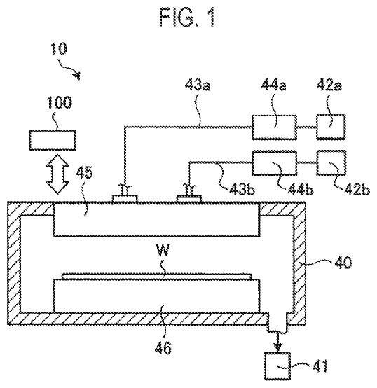

FIG. 1 is a view illustrating an example of a film forming apparatus according to an embodiment of the present disclosure. In the present embodiment, a film forming apparatus 10 is, for example, a chemical vapor deposition (CVD) apparatus.

The film forming apparatus 10 includes a container 40, an exhaust device 41, and a controller 100. The exhaust device 41 exhausts gas in the container 40. The interior of the container 40 becomes a predetermined vacuum atmosphere by the exhaust device 41.

A raw material source 42a that accommodates isocyanate, which is a raw material monomer remaining in a liquid state, is connected to the container 40 through a supply pipe 43a. A raw material source 42b that accommodates amine, which is a raw material monomer remaining in a liquid state, is connected to the container 40 through a supply pipe 43b. Isocyanate is an example of a first component, and amine is an example of a second component.

The liquid of isocynate supplied from the raw material source 42a is vaporized by a vaporizer 44a provided in the supply pipe 43a. The vapor of isocynate is introduced into a shower head 45 used as a gas discharge part through the supply pipe 43a. Further, the liquid of amine supplied from the raw material source 42b is vaporized by a vaporizer 44b provided in the supply pipe 43b. The vapor of amine is introduced into the shower head 45.

The shower head 45 is provided in, for example, an upper portion of the container 40, and has a plurality of discharge holes formed in a lower surface of the shower head 45. The shower head 45 discharges the vapor of isocyanate and the vapor of amine, which are introduced through the supply pipe 43a and the supply pipe 43b, from separate discharge holes into the container 40 in the form of a shower.

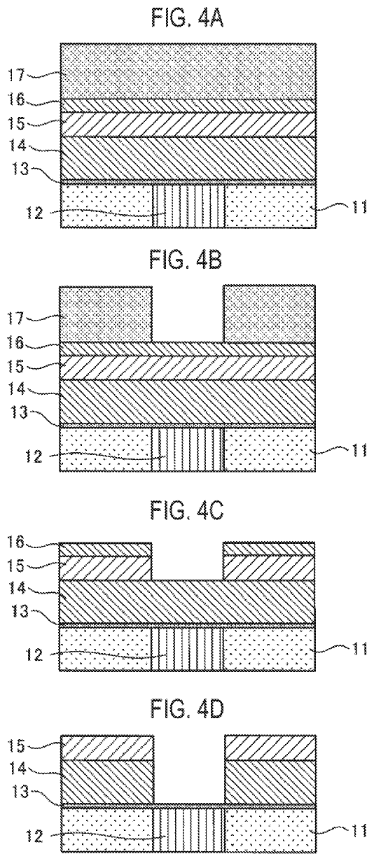

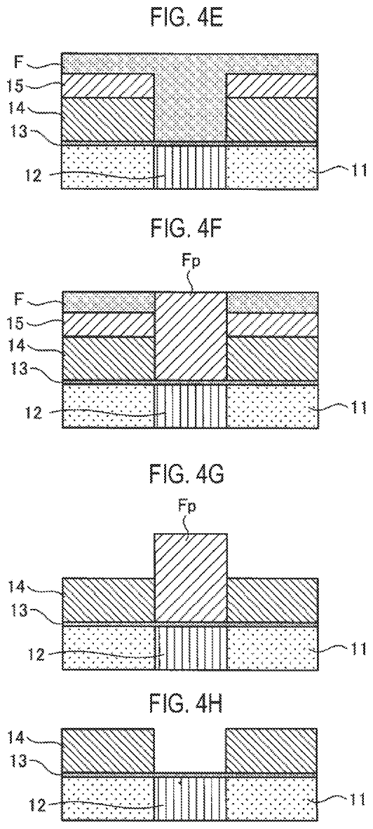

A stage 46 equipped with a temperature adjusting mechanism (not illustrated) is provided inside the container 40. A workpiece W is placed on the stage 46. The stage 46 controls a temperature of the workpiece W to a predetermined temperature by the temperature adjusting mechanism. In a case where a urea film F (see FIG. 4E) is formed on the workpiece W, the stage 46 controls the temperature of the workpiece W to a temperature suitable for a vapor deposition polymerization of the raw material monomers supplied from the raw material source 42a and the raw material source 42b. The temperature suitable for the vapor deposition polymerization may be determined according to the kinds of the raw material monomers. For example, the temperature may be 40 degrees C. to 150 degrees C.

By causing the two kinds of raw material monomers to undergo a vapor deposition polymerization reaction on a front surface of the workpiece W with the film forming apparatus 10 configured as above, it is possible to laminate the urea film F on the front surface of the workpiece W. When the two kinds of raw material monomers are isocyanate and amine, the urea film F composed of a urea compound is laminated on the front surface of the workpiece W.

Thereafter, the urea film F is irradiated with an ultraviolet ray of a predetermined wavelength (for example, 172 nm). A cross-linking reaction proceeds between molecules of the urea compound at a location irradiated with the ultraviolet ray. By the cross-linking reaction, a polymer composed of the urea compound as a raw material is produced and a cross-linking film Fp (see FIG. 4F) is obtained.

The cross-linking film Fp is cleaned with solvent or the like, so that the urea film F or the cross-linking film Fp from which a non-reacted raw material monomer is removed can be obtained. The cross-linking film Fp may be used as a burying protective film, a mask patterning or a sacrificial film.

The controller 100 includes a memory, a processor, and an input/output interface. The processor controls various parts of the film forming apparatus 10 through the input/output interface by reading and executing a program or a recipe stored in the memory.

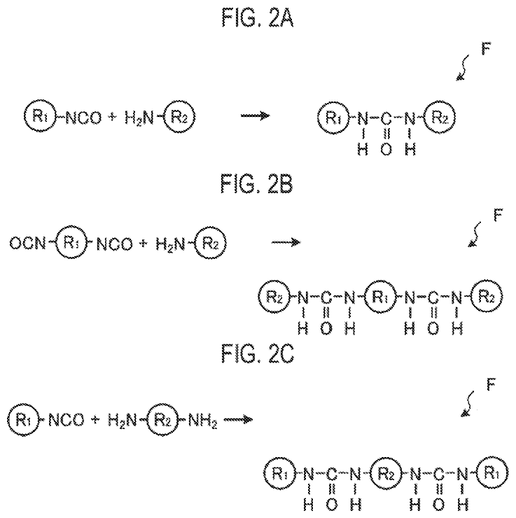

Next, specific examples of the first component and the second component will be described with reference to FIGS. 2A to 2C. FIGS. 2A to 2C is a diagram illustrating a polymerization reaction in which the urea film F is formed. As illustrated in FIGS. 2A to 2C, in the urea film F according to the embodiment of the present disclosure, at least one of isocyanate as the first component and amine as the second component is a monofunctional compound.

Specifically, as illustrated in FIG. 2A, the urea film F is produced by a polymerization reaction between a monofunctional monoisocyante compound and a monofunctional monoamine compound. In this case, a urea compound having one urea bond is laminated as the urea film F.

Further, as illustrated in FIG. 2B, the urea compound that constitutes the urea film F may be a combination in which the first component is a difunctional diisocyanate compound and the second component is a monoamine compound.

Further, as illustrated in FIG. 2C, the urea compound that constitutes the urea film F may be a combination in which the first component is a monoisocyanate compound and the second component is a difunctional diamine compound.

As described above, at least one of the first component and the second component is a monofunctional compound. Thus, it is possible to appropriately control the molecular weight of the urea compound after the vapor deposition polymerization. That is, by using each of the first component and the second component as the difunctional compound, the urea compound of a polymer is produced.

Meanwhile, when one of the first component and the second component is monofunctional, it becomes possible to make the molecular weight of the urea compound smaller as compared with the case in which each of the first component and the second component is difunctional. Accordingly, it is possible to improve the solubility of the urea film F to various organic solvents as compared with the urea compound of a polymer. Further, the molecular weight of the urea compound that forms the urea film F is not particularly limited and may be 1,000 or less.

When the first component is monofunctional, specific examples of the monoisocyanate compound may include t-butylisocyanato, n-butylisocyanato, cyclohexylisocyanato, benzylisocyanato, m-tolylisocyanato, and the like.

Further, when the first component is difunctional, specific examples of the diisosyanate compound may include 1,3-bis(isocyanatomethyl)cyclohexane, m-xylenediamine, 1,4-phenylenediamine, hexamethylenediisocyanato, and the like.

Further, when the second component is monofunctional, specific examples of the monoamine compound may include n-butylamine, t-butylamine, cyclohexylamine, benzylamine, m-toluidine, and the like.

Further, when the second component is difunctional, specific examples of the diamine compound may include 1,3-bis(aminomethyl)cyclohexane, m-xylenediamine, 1,4-phenylenediamine, 1,4-diaminobutane, 1,6-diaminohexane, piperazine, and the like.

When at least one of the first component and the second component is monofunctional, the other may be trifunctional or more than trifunctional. A specific example of the case in which the second component is trifunctional may include tris(aminomethyl)amine. Further, from the viewpoint of making the distribution of the molecular weight of the urea compound uniform, the first component or the second component may be monofunctional or a combination of monofunctional and difunctional.

Further, the first component and the second component are not limited to the aforementioned examples. Compounds selected from the group of an aromatic compound, a xylene-based compound, an alicyclic compound, and an aliphatic compound may be suitably used as the first and second components.

Further, when a diisocyanate compound is used as the first component, for example, there may be a case where a diisocyanate compound as a raw material becomes a diamine compound by hydrolysis. In this case, polymerization reaction between such a diamine compound and the isocyanate compound may concur. Thus, it is preferable that the multifunctional compound is amine rather than isocyanate.

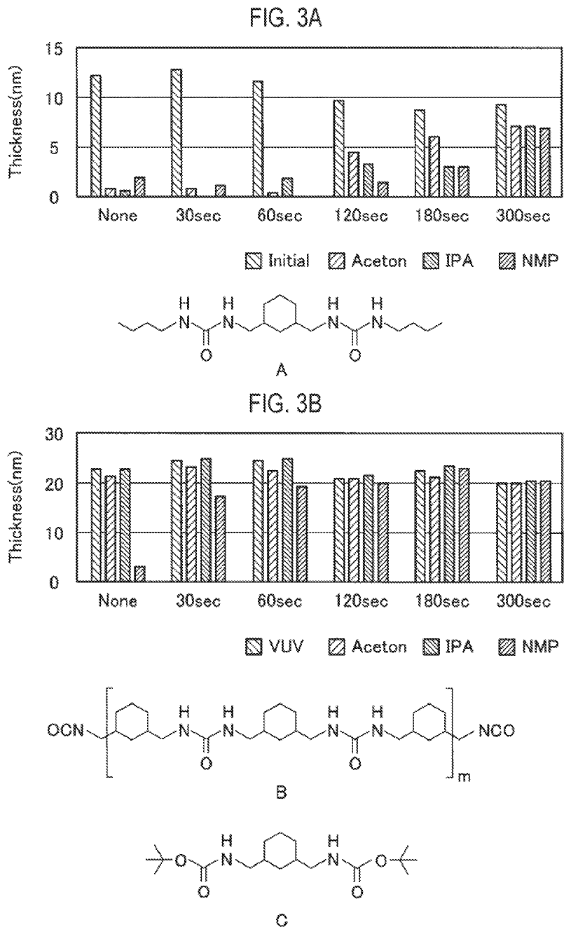

Next, the solubility after the cross-linking reaction in the case where a monofunctional compound is used as the first component and the second component and the case where a difunctional compound is used as the first component and the second component will be described with reference to FIGS. 3A and 3B.

FIG. 3A is a graph illustrating the solubility of the composite for film formation according to an embodiment of the present disclosure. FIG. 3B is a graph illustrating a comparative example of the solubility of the composite for film formation in the embodiment of the present disclosure.

In FIG. 3A, the solubility of a urea compound A after the cross-linking reaction in which 1,3-bis(isocyanatomethyl)cyclohexane is used as the first component and n-buthylamine is used as the second component is illustrated. In FIG. 3B, the solubility of a polyurea compound B after the cross-linking reaction is illustrated as a comparison result.

The cross-linking reaction was conducted on the urea compound A or the polyurea compound B under a cross-linking condition that the urea compound A or the poly urea compound B is irradiated with light of a wavelength of 172 nm in a nitrogen atmosphere at a temperature of 20 degrees C. for 0 seconds, 30 seconds. 60 seconds, 120 seconds, 180 seconds, and 300 seconds, respectively.

Further, the evaluation on the solubility was conducted by cleaning a film after the cross-linking reaction with each solvent (acetone, IPA, and NMP) at 20 degrees C. for 1 minute, and subsequently measuring thicknesses of the film before and after the cleaning.

As illustrated in FIG. 3A, it was found that, for the urea compound A, the thickness of the film tends to gradually increase according to the irradiation time of the ultraviolet ray even if any solvent is used. Specifically, it was confirmed that the solubility becomes higher as the irradiation time of the ultraviolet ray grows shorter even if any solvent is used. For example, when the irradiation time was 300 seconds, the solubility showed a decreasing trend.

This means that, when the urea compound A was irradiated with an ultraviolet ray for 300 seconds, the cross-linking reaction between the molecules of the urea compound A proceeded sufficiently.

Meanwhile, as illustrated in FIG. 3B, it was found that the polyurea compound B was soluble in an NMP to a certain extent before the cross-linking reaction (0 seconds), but the solubility of the polyurea compound B was low for the solvent other than NMP.

Further, as illustrated in FIG. 3B, it was confirmed that, even though the polyurea compound B was continuously irradiated with an ultraviolet ray, no significant difference between the solubilities of the polyurea compound B to the solvents was shown. That is, since no sufficient difference between the solubilities of the polyurea compound B was shown before and after the cross-linking reaction, it is difficult to remove the polyurea compound B remaining in an unreacted state in the cross-linking reaction with the solvent.

In contrast, a difference between the solubilities of the urea compound A before and after the cross-linking reaction was shown. Thus, it is possible to easily remove the urea compound remaining in an unreacted state in the cross-linking reaction with the solvent. That is, for example, in a case where the urea film F is irradiated with an ultraviolet ray and the cross-linking film Fp is used for the patterning of the mask, line edge roughnesses of the cross-linking film Fp and the urea film F can be reduced.

Further, in a case where a urethane compound C illustrated in FIG. 3B is used as a comparative example of the urea compound A, a variation in change of the solubility was small even if the urethane compound C is irradiated with an ultraviolet ray. It is considered that this is because the hydrogen bond between the molecules of the urea compound A is stronger than that of the urethane compound C.

That is, since the urea compound A takes a conformation in which the cross-linking reaction is likely to proceed, in advance by the inter-molecule hydrogen bond, the cross-linking reaction proceeds rapidly through the irradiation of the ultraviolet ray. Meanwhile, the urethane compound C is poor in the inter-molecule hydrogen bond. Thus, even though the urethane compound C is irradiated with an ultraviolet ray, the cross-linking reaction is hard to proceed.

As described above, in order to obtain a sufficient difference between the solubilities before and after the cross-linking reaction, the urea compound A having a small molecular weight may be used rather than the polyurea compound B, and the urea compound A may have the urea bond rather than the urethane bond.

Further, in order to obtain a sufficient difference between the solubilities before and after the cross-linking reaction, one of the first component and the second component may be an aromatic compound and the other may be an aliphatic compound. In this case, the aromatic portion is likely to absorb an ultraviolet ray, thus facilitating the cross-linking reaction. In the aliphatic portion, the solubility of the urea compound remaining in an unreacted state in the cross-linking reaction to the solvent, can be improved. Further, the aliphatic compound used herein may be a chained compound or a cyclic compound.

Further, a xylene-based compound may be used as one of the first component and the second component. The xylene-based compound has the characteristics of both the aromatic compound and the aliphatic compound. Thus, it is possible to contribute to the facilitation of the cross-linking reaction and the improvement of the solubility with one molecule. Further, the xylene-based compound used herein collectively refers to as a compound having isocyanate or amine in place of benzyl.

Next, a specific use example of the urea film F will be described with reference to FIGS. 4A to 4H. FIGS. 4A to 4H are cross-sectional views illustrating examples of states of the workpiece W in respective processes. Here, the case in which the urea film F is used as the burying protective film will be described as an example, but the present disclosure is not limited thereto. The urea film F may be used as patterning of a mask or a sacrificial film.

As illustrated in FIG. 4A, the workpiece W is provided by laminating an etching stopper film 13, a second interlayer insulation film 14, a planarization layer (organic planarization layer (OPL) or spin on carbon (SoC)) 14, an anti-reflection film 16, and a resist layer 17 on a first interlayer insulation layer 11 and a copper wiring line 12 in a sequential manner.

As illustrated in FIG. 4B, the workpiece W illustrated in FIG. 4A is subjected to photography to remove a portion of the resist layer 17. Thereafter, as illustrated in FIG. 4C, the workpiece W is subjected to oxygen plasma-based etching to remove portions of the anti-reflection film 16 and the planarization layer 15.

Subsequently, as illustrated in FIG. 4B, the workpiece W illustrated in FIG. 4C is subjected to fluorocarbon plasma-based etching to remove a portion of the second interlayer insulation film 14 and the anti-reflection film 16.

Subsequently, as illustrated in FIG. 4E, the urea film F is formed on the front surface of the workpiece W illustrated in FIG. 4D by causing the vapor deposition polymerization using the first component and the second component on the workpiece W.

Subsequently, the cross-linking reaction proceeds on a portion of the urea film F by irradiating the workpiece W illustrated in FIG. 4E with an ultraviolet ray through a mask. As a result, as illustrated in FIG. 4F, the workpiece W in which the portion of the urea film F is modified into the cross-linking film Fp is obtained.

Thereafter, the workpiece W illustrated in FIG. 4F is cleaned with a certain solvent to remove the urea film F and the planarization layer 15 under the urea film F. As a result, the workpiece W as illustrated in FIG. 4G is obtained.

Thereafter, the workpiece W illustrated in FIG. 4G is ashed to remove the cross-linking film Fp. As a result, the workpiece as illustrated in FIG. 4H is obtained.

As described above, in the case in which the urea film F and the cross-linking film Fp are used as the burying protective films, it is possible to easily remove only the urea film F while leaving the cross-linking film Fp based on a difference between the solubilities of the urea film F and the cross-linking film Fp to the organic solvent. In other words, it is possible to remove residues of the urea film F while leaving the cross-linking film Fp.

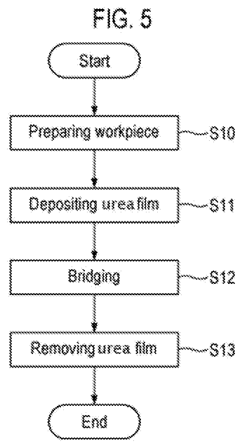

Next, a process sequence of a film forming method according to an embodiment will be described with reference to FIG. 5. FIG. 5 is a flowchart illustrating an example of the film forming method according to the embodiment of the present disclosure. As illustrated in FIG. 5, the workpiece W is prepared (step S10). The urea film F is deposited on the workpiece W by the vapor deposition polymerization between the first component and the second component (step S11).

Subsequently, a portion of the urea film F is irradiated with an ultraviolet ray to cause the molecules of the urea compound of the urea film F to be cross-linked with each other (step S12). Further, in the case where the urea film F is used as a sacrificial film, processes following to step S12 may be omitted.

Further, in this case, the urea film F can be removed by cleaning using solvent or ashing. Subsequently, the urea film F is removed by cleaning the workpiece W with the organic solvent (step S13).

### [Others]

Further, the technology described in the present disclosure is not limited to the above embodiments, and various modifications may be made within the scope of the present disclosure.

For example, in the above embodiments, the case where the workpiece W is a semiconductor wafer has been described as an example, but the present disclosure is not limited thereto. The substrate to be processed may be another substrate such as a glass substrate.

Further, in the above embodiments, capacitive coupled plasma (CCP) has been described to be used as an example of the plasma source, but the technology of the present disclosure is not limited thereto. Example of the plasma source may include induction coupled plasma (ICP), macro wave excitation surface wave plasma (SWP), electron cyclotron resonance plasma (ECP), helicon wave excitation plasma (HWP), and the like.

Further, in the above embodiments, for example, the polymer film has been described to be laminated by the vapor deposition polymerization using vapors of two kinds of raw material monomers, but the technology of the present disclosure is not limited thereto. For example, the polymer film may be laminated on the workpiece W by coating the workpiece W with a mixture of the liquids of the monomers. That is, the method of forming the polymer film may be a coating method.

According to the present disclosure in various aspects and embodiments, it is possible to easily form a film.

It should be noted that the embodiments disclosed herein are exemplary in all respects and are not restrictive. Indeed, the above embodiments may be implemented in various forms including the coating method. Further, the above embodiments may be omitted, replaced or modified in various forms without departing from the scope and spirit of the appended claims.

What is claimed is:

1. A composite for film formation, comprising: a first component and a second component that are polymerized with each other to produce a urea compound,
wherein at least one of the first component and the second component is a monofunctional compound.

2. The composite for film formation of claim 1, wherein one of the first component and the second component is isocyanate and the other of the first component and the second component is amine.

3. The composite for film formation of claim 2, wherein one of the first component and the second component is a monofunctional compound, and the other of the first component and the second component is a multifunctional compound including a difunctional compound or a compound that is more than difunctional.

4. The composite for film formation of claim 3, wherein the multifunctional compound is the difunctional compound.

5. The composite for film formation of claim 4, wherein the multifunctional compound is amine.

6. The composite for film formation of claim 4, wherein one of the first component and the second component is an aromatic compound and the other of the first component and the second component is an aliphatic compound.

7. The composite for film formation of claim 3, wherein the multifunctional compound is amine.

8. The composite for film formation of claim 2, wherein one of the first component and the second component is an aromatic compound and the other of the first component and the second component is an aliphatic compound.

9. The composite for film formation of claim 1, wherein one of the first component and the second component is a monofunctional compound, and the other of the first component and the second component is a multifunctional compound including a difunctional compound or a compound that is more than difunctional.

10. A film forming method comprising:
depositing a first component and a second component on a workpiece, the first component and the second component being polymerized with each other to produce urea compounds, and at least one of the first component and the second component being a monofunctional compound; and
irradiating the urea compounds with an ultraviolet ray to cause the urea compounds to be cross-linked with each other.
